(19) United States
(12) Patent Application Publication
(10) Pub. No.: US 2026/0333882 A1
(43) Pub. Date: Oct. 22, 2026

(54) FORM BODY AND METHOD FOR A PHOTOVOLTAIC MODULE

(71) Applicant: Sunmaxx PVT GmbH, Ottendorf-Okrilla (DE)

(72) Inventors: Wilhelm Stein, Dresden (DE); Jiri Springer, Dresden (DE)

(21) Appl. No.: 19/099,657

(22) PCT Filed: Jun. 29, 2023
(86) PCT No.: PCT/EP2023/067827

§ 371 Date: Jan. 29, 2025

(30) Foreign Application Priority Data
Aug. 2, 2022 (DE) 10 2022 119 331.4
Jan. 16, 2023 (DE) 10 2023 100 868.4

(51) Int. Cl. H10F 19/80; H10F 71/00

(52) U.S. Cl. CPC H10F 19/807; H10F 71/128

(57) ABSTRACT

In an embodiment a form body configured for producing a photovoltaic module includes a top side concavely or convexly curved in an upward direction configured for curving a layer stack of the photovoltaic module, the layer stack having at least two layers.

### CROSS-REFERENCE TO RELATED APPLICATIONS

This patent application is a national phase filing under section 371 of PCT/EP2023/067827, filed Jun. 29, 2023, which claims the priority of German patent application no. 102022119331.4, filed Aug. 2, 2022, and German patent application no. 102023100868.4, filed Jan. 16, 2023 each of which is incorporated herein by reference in its entirety.

### TECHNICAL FIELD

A form body for producing a photovoltaic module is disclosed, in particular for producing a photovoltaic-thermal module. Furthermore, a method for processing a layer stack for a photovoltaic module is disclosed, in particular for a photovoltaic-thermal module.

### BACKGROUND

The publication WO 2015/184402 relates to a photovoltaic module with an integrated liquid cooling system.

### SUMMARY

Embodiments of the disclosure relate to a molded body for manufacturing a photovoltaic module, in particular a photovoltaic-thermal module. Further embodiments of the disclosure relate to a method for processing a layer stack for a photovoltaic module, in particular for a photovoltaic-thermal module. In particular, the method is part of a manufacturing method for a photovoltaic module. For example, a form body according to at least one of the embodiments described herein is used in the method. Features, advantages and further developments of the form body thus also apply to the method and vice versa.

The form body comprises a top side that is concavely or convexly curved in an upward direction. The form body with the curved top side is configured for curving a layer stack for the photovoltaic module. The layer stack comprises at least two layers. The layer stack is subsequently part of the photovoltaic module. The two layers comprise, for example, a PV laminate with a glass pane, a lamination film and/or a planar heat sink. For example, solar cells are already connected to the glass pane and the planar heat sink is attached to the glass pane with the solar cells by lamination.

For example, the photovoltaic module is a conventional photovoltaic module without a heat sink. For example, the photovoltaic module comprises crystalline solar cells and/or thin-film solar cells. The two layers, for example, comprise a PV laminate with a glass pane and the crystalline solar cells. The two layers comprise, for example, a PV laminate with a glass pane and the thin-film solar cells. The form body can be used to intentionally produce curved modules, for example for facades. It is also possible to use the form body to compensate for unwanted curvature in conventional photovoltaic modules in order to achieve modules that are as flat as possible.

The layer stack can be curved or bent using the molded body. During the production of the photovoltaic module, it is thus possible to bend the layer stack as desired with the help of the molded body. In particular, this curvature compensates for stresses that can arise in the layer stack due to different coefficients of thermal expansion. Without the form body, these stresses would lead to an unwanted warpage of the layer stack. The form body allows the layer stack to be warped in the opposite direction during production, so that the stresses due to the different coefficients of thermal expansion subsequently exactly compensate for this warpage and a flat layer stack is obtained. This layer stack no longer warps unintentionally due to different coefficients of thermal expansion of the layers of the layer stack.

Due to its convex or concave shape, the form body is also referred to as a lens, in particular as a mechanical lens. In the context of this disclosure, a concave curvature along the upward direction is understood to be, in particular, an inwardly curved shape of the top side, wherein the upward direction is perpendicular to a main plane of extension of the top side. Accordingly, a convex curvature is to be understood as an outwardly curved shape, wherein the upward direction is perpendicular to a main plane of extension of the top side.

According to at least one embodiment, the form body comprises a plurality of flat extended plates. The plates are stacked on top of each other along the upward direction. The upward direction is oriented transversely to the flat extension. In particular, the flat extended plates comprise a different size of flat extension to each other. Thus, the curved form body can be formed by the plates stacked on each other. For example, to form the convex top side, the plates extended in the upward direction become smaller. For example, the top side is configured by a flat end plate that covers the stacked plates at the top. This makes it possible to realize a flat top side.

According to at least one embodiment, the form body comprises a plurality of rods as an alternative or in addition to the plurality of plates. The rods are each elongated along the upward direction. The rods are arranged next to each other transversely to the upward direction. The curved top side can be formed by rods of different lengths. It is also possible to combine plates and rods, for example, in the upward direction, first flat extended plates and then elongated rods.

According to at least one embodiment, the form body is formed from a solid body. Thus, the form body is configured as a single piece. For example, the form body is milled from a single block of material.

According to at least one embodiment, the top side is full-surface. In particular when using a solid body and/or when using the majority of the plates, the top side is configured as a full surface. The top side can also be configured as a full-surface area when using rods. In this case, however, an additional covering layer must be applied to the top side of the rods. Alternatively, it is also possible for the top side to comprise one or more clearances. For example, the spaces between the rods are referred to as a clearance. It is also possible to apply a cover structure, for example a wire mesh, to the rods to form the top side with the clearances. Alternatively, a full-surface cover plate is provided to form a flat top side on the rods.

According to at least one embodiment, the top side is curved only along a longitudinal axis. The longitudinal axis extends transversely to the upward direction. The top side is not curved along a transverse axis, which extends transversely to the longitudinal axis and to the upward axis. Along the transverse axis, the top side is rectilinear.

According to at least one further embodiment, the top side is curved along the longitudinal axis and along the transverse axis. Thus, using the form body, a curving of the layer stack is possible along all spatial directions in a single curving process.

According to at least one embodiment, the form body comprises a thermal conductivity of at least 30 W/(m·K), in particular 50 W/(m·K). The form body comprises a thermal conductivity that is sufficiently high to conduct heat to be introduced into and/or removed from the layer stack during production and processing sufficiently well. Other values for the thermal conductivity are also possible. For example, a thermal conductivity of at least 100 W/(m·K) or at least 400 W/(m·K). Due to the sufficiently high thermal conductivity, the molded body enables the layer stack to be cooled after a lamination process for the connection of the layers of the layer stack. It is also possible to use the mold body during the lamination process. In this case, the mold body conducts the heat necessary for the lamination to the layer stack due to its sufficiently high thermal conductivity. According to some embodiments, the layer stack cools on the mold body. According to further embodiments, the layer stack does not cool on the mold body, but is still heated after lamination and is removed from the mold body. According to further embodiments, the layer stack is not laminated on the mold body, but is applied to the mold body after lamination and is curved, in particular in a heated state.

According to at least one embodiment, the form body is formed from a plastic. According to at least one further embodiment, the form body is additionally or alternatively formed from a metal, for example from aluminum or steel. It is possible that the form body comprises only a single material or is formed from a combination of materials.

According to at least one embodiment, the method comprises providing the layer stack. The layer stack is stacked on a form body according to one of the embodiments described here, so that the layer stack rests against the form body, in particular against the top side of the form body. As a result, the layer stack is curved using the form body. Subsequently, the layer stack is released from the form body. After release, the layer stack is particularly flat. The stresses due to the different coefficients of thermal expansion counteract the curvature of the layer stack and thus equalize it at the intended operating temperatures of the photovoltaic module. According to at least one further embodiment, the method comprises heating the layer stack. The heating serves to laminate at least part of the layer stack while the layer stack is in contact with the form body. Thus, warping and laminating of the layer stack can be carried out in a single process.

According to at least one further embodiment, the method comprises reducing a temperature of the layer stack while the layer stack is in contact with the form body. The layer stack cools down after lamination, while the layer stack is curved by the form body. The cooling step of the layer stack while it is in contact with the mold body is also possible if the layer stack has been laminated independently of the mold body and thus is not in contact with the mold body during lamination. In this case, after lamination, the layer stack is placed against the top side of the mold body and curved before cooling.

According to at least one embodiment, the layer stack is provided with at least one metallic planar heat sink and a glass pane. The metallic planar heat sink and the glass pane comprise the different coefficients of thermal expansion. By the curvature, a flat formation of the metallic planar heat sink and the glass pane can nevertheless be realized, so that subsequently during operation of the photovoltaic module no unwanted stresses and curvatures occur.

### BRIEF DESCRIPTION OF THE DRAWINGS

Further advantages, features and developments are explained below with reference to the drawings. The same reference signs indicate the same elements in the individual figures. No true-to-scale references are shown; rather, individual elements may be shown exaggeratedly large or thick for better understanding.

FIG. 1A shows a schematic representation of a form body with a layer stack according to an embodiment;

FIG. 1B shows a schematic representation of a photovoltaic-thermal module according to an embodiment;

FIG. 2 shows a schematic representation of a form body with a layer stack according to an embodiment;

FIGS. 3A to 3G each show schematic representations of the form body according to different views and/or embodiments; and

FIG. 4 shows a schematic sectional view of an embodiment of a photovoltaic-thermal module.

### DETAILED DESCRIPTION OF ILLUSTRATIVE EMBODIMENTS

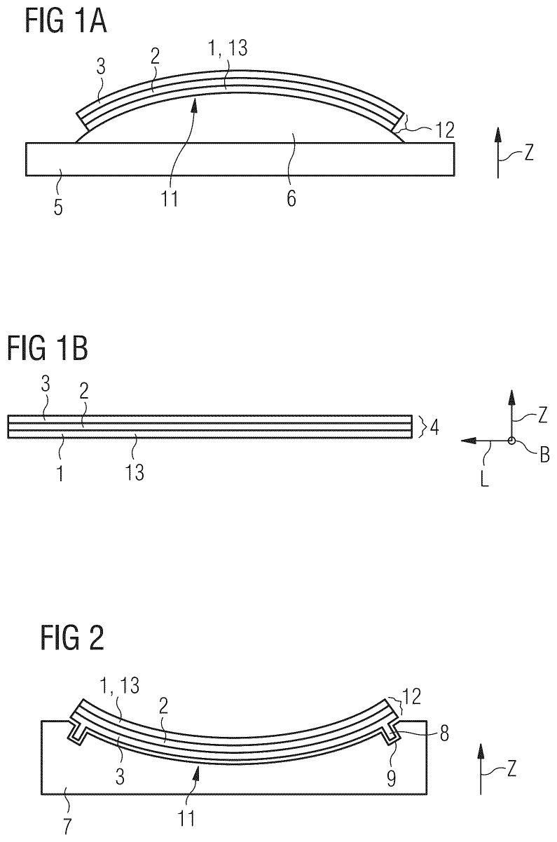

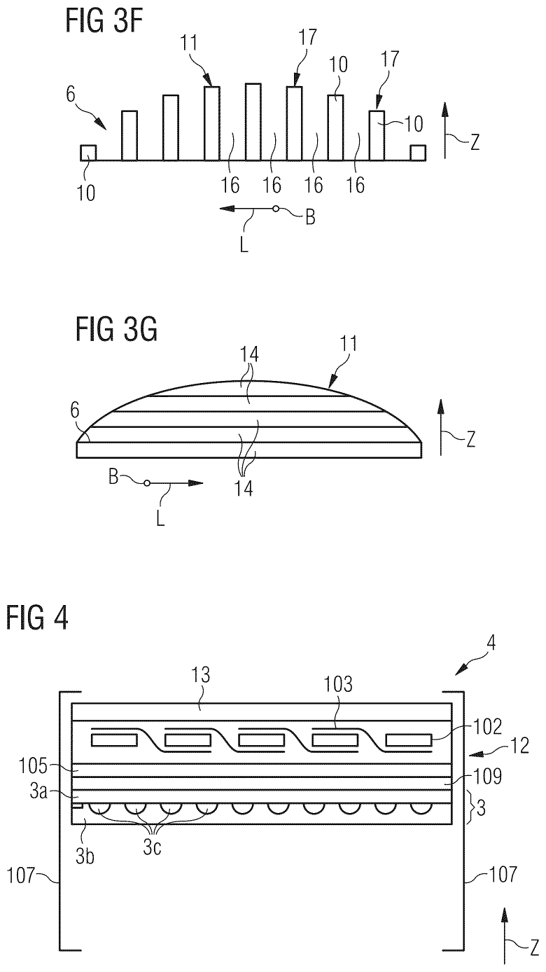

A photovoltaic-thermal module 4 (FIG. 1B, FIG. 4), referred to in short as a PVT module, combines photovoltaic modules for electrical power generation with the use of waste heat from the modules. PVT modules thus convert solar energy into electricity and the waste heat that occurs in the process is made usable. In addition to electrical energy, such PVT modules also produce heat, for example in the form of hot water or other cooling liquids.

The PVT module 4 comprises a layer stack 12. The layer stack 12 comprises a plurality of layers stacked along an upward direction Z. In particular, the layer stack 12 comprises a PVT laminate 1 having a glass pane 13. The layer stack 12 comprises a lamination film 2. The lamination film 2 is arranged between the PVT laminate 1 and a planar heat sink 3. In particular, the PVT laminate 1 additionally comprises solar cells 102, electrical cell connectors 103 and further elements in order to form the photovoltaic part of the PVT module 4.

The layers of the layer stack 12 are joined by a lamination process under the influence of high temperatures. For example, temperatures of 130 °C to 150 °C are used for this purpose, so that the PV laminate 1 is connected to the planar heat sink 3 by the lamination film 2.

FIG. 1A shows the layer stack 12 during a manufacturing or processing step.

The layer stack 12 can be curved by a form body 6. The form body 6 comprises a convexly curved top side 11. The top side thus bulges outwards in the upward direction Z. The layer stack 12 is pressed against the top side 11, so that the layer stack 12 is also bulged due to the bulging top side 11.

In the illustrated embodiment of FIG. 1 with the convexly curved form body 6, the PV material 1 lies directly on the form body 6 and the planar heat sink 3 faces away from the form body 6. The layer stack 12 is placed on the form body 6 in such a way that the PV material 1 faces the top side 11 and, in particular, is in direct contact with the top side 11.

The form body 6 is thermally and/or mechanically connected to a heating plate or cooling plate 5. It is possible that the form body 6 is arranged in a lamination furnace for laminating the PV material 1 to the planar heat sink 3. The layer stack 12 is arranged on the top side 11 and curved during the lamination process. The heating plate 5 transfers heat to the layer stack 12 by the form body 6. The form body 6 comprises a material with sufficiently good heat conductivity for this purpose.

It is also possible to laminate the layer stack 12 independently of the form body 6. The layer stack 12 is laminated in the conventional manner, for example.

After the lamination process, both when the layer stack 12 is placed on the form body 6 during lamination and when the lamination process takes place without the form body 6, the layer stack 12 cools on the form body 6. For example, after lamination, the layer stack 12 is still at high temperature placed on the top side 11 and pressed on so that the layer stack 12 is curved according to the top side 11.

The curvature of the layer stack 12 has the effect of equalizing stresses and curvatures in the layer stack 12 that occur during cooling. The planar heat sink 3, which is stretched more than the PV laminate 1, contracts more than the PV material 1 and especially than the glass pane 13 during cooling. This contraction causes the curvature induced by the form body 6 to be compensated. Due to the cooling, the layer stack 12 bulges in exactly the opposite direction to the bulge induced by the form body 6.

The cooled layer stack 12 thus comprises a flat expansion along a plane transverse to the upward direction Z at normal operating temperatures of, for example, −30 °C to +80 °C. Undesired warping, which can conventionally occur during cooling or during operation due to temperature fluctuations, can thus be avoided or at least reduced. FIG. 1B schematically shows such a layer stack 12 or the photovoltaic-thermal module after cooling. The PVT module 4 comprises no unwanted curvatures along the upward direction Z and is arranged flat along a plane that is stretched by a longitudinal axis L and a transverse axis B. The longitudinal axis L, the transverse axis B and the upward direction Z are arranged in particular perpendicular to each other.

For example, the form body 6 comprises a maximum dimension in the range from 2 cm to 10 cm along the upward direction Z, in particular in the range from 3 cm to 6 cm.

For example, the form body 6 comprises a maximum expansion along the transverse axis B in a range from 0.8 m to 1.5 m, in particular in a range from 1.1 m to 1.2 m.

For example, the form body 6 comprises a maximum dimension in a range of 1.5 m to 2 m along the longitudinal axis L, in particular in a range of 1.7 m to 1.8 m.

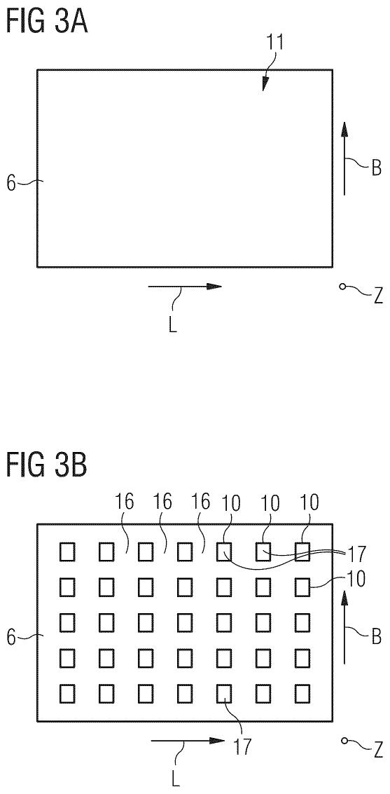

FIG. 2 schematically shows a further embodiment of the form body 7. Different to the form body 6, the form body 7 is concavely curved so that the top side 11 comprises a concave curvature along the upward direction Z. Otherwise, it is possible that the form body 6 and the form body 7 are constructed in the same way.

During processing, the layer stack 12 is placed on the top side 11 in such a way that the planar heat sink 3 faces the form body 7. The PV laminate 1 and in particular the glass pane 13 are arranged facing away from the form body 7. For example, the PV laminate 3 is in direct contact with the top side 11 of the form body 7. This arrangement allows the layer stack 12 to curve, comparable to the embodiment of FIG. 1A, in which the planar heat sink 3 is stretched more than the PV laminate 1 and in particular than the glass pane 13. After cooling, a planar photovoltaic-thermal module 4 according to FIG. 1B can be realized.

The form body 7 comprises one or more recesses 9. The recesses 9 serve to accommodate connectors 8 of the PVT module 4. The connectors 8 are, for example, hydraulic connectors and/or electrical connections. The recesses 9 allow sufficient contacting between the top side 11 and the planar heat sink 3 despite the connector 8.

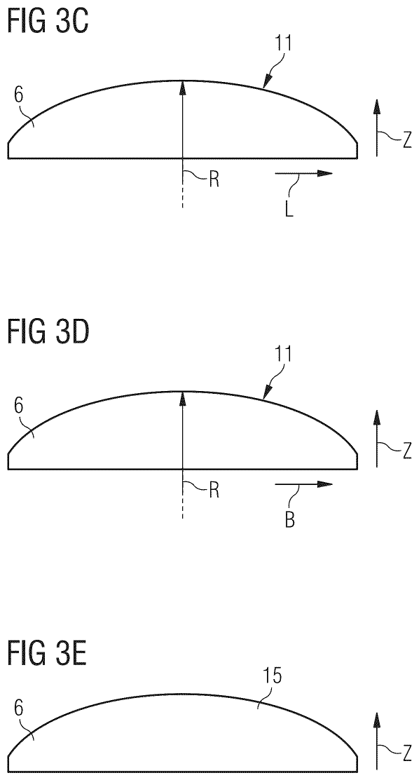

FIGS. 3A to 3G show schematic views and various embodiments of the form body 6. The concavely curved form body 7 comprises the same features and designs in accordance with the embodiments. Therefore, the features are explained below in connection with the form body 6 and also apply equally to the form body 7.

FIG. 3A shows a view along the upward direction Z onto the surface 11 of the form body 6. The top side 11 according to FIG. 3A is configured as a full-surface and in particular comprises no interruptions. This allows for a large contact surface between the PV material 1 and the top side 11. To form the full-surface top side 11, the form body 6 is formed, for example, from a solid body 15 (FIG. 3E). For example, the form body 6 with the continuous top side 11 is configured from a single block of material, for example milled out, and the solid body 15 is configured in this way.

FIG. 3B shows a view along the upward direction Z of the form body 6 according to a further embodiment. The form body 6 is configured from a plurality of rods 11. The rods are arranged in the same direction next to one another. The rods 10 extend along the upward direction Z. Ends 17 of the rods 10 form the top side 11 of the form body 6.

The top side 11 comprises clearances 16 between the rods 10. The top side 11 is thus not configured as a full-surface, but rather with interruptions, which are formed by the clearances 16. The rods 10 are arranged in such a way that the curved top side 11 is configured. In particular, the rods 10 comprise different lengths along the upward direction Z for this purpose. In the intermediate spaces and through the clearance 16, in particular good heat transport is possible, for example to enable good cooling of the layer stack 12.

FIG. 3C shows a sectional view or a side view of the form body 6 along a plane that is spanned by the longitudinal axis L and the upward direction Z. The curvature of the top side 11 along the upward direction Z can be seen in the view. The curvature comprises a radius R. For example, the radius comprises a value in a range from 1.5 m to 13 m.

FIG. 3D shows a sectional view along a plane spanned by the transverse axis B and the upward direction Z, in particular a plane transverse to the plane of FIG. 3C. For example, the radius comprises a value in a range from 1 m to 10 m.

The form body 6 is, for example, curved at the top side 11 as shown in FIGS. 3C and 3D. The curvature comprises a radius R.

The curvature is thus configured along the longitudinal axis L (FIG. 3C) and along the transverse axis B (FIG. 3D). It is possible that the two radii shown in FIGS. 3C and 3D are the same. It is also possible that the two radii shown in FIGS. 3C and 3D are different.

It is also possible that the form body 6 is only curved along one of the longitudinal axis L and the transverse axis B, i.e. either as shown in FIG. 3C or as shown in FIG. 3D, but not both. Along the other of the longitudinal axis L and the transverse axis B, the form body 6 is not curved, but comprises a straight course of the top side 11 in the sectional view.

FIG. 3F shows a side view of the form body 6 according to FIG. 3B. The rods 10 are arranged next to one another along the longitudinal axis L and the transverse axis B. The ends 17 together form the top side 11. The clearances 16 are arranged between the rods 10.

FIG. 3G shows the form body 6 according to a further embodiment. The form body 6 is formed from a plurality of flat extended plates 14. The plates 14 are each flat extended along the longitudinal axis L and the transverse axis B. The plates 14 are stacked on top of one another in the upward direction Z. The plates 14 comprise different flat extensions, in particular with respect to one another. In the upward direction Z, for example, the plates 14 become smaller and smaller, so that the curved top side 11 is configured.

Combinations of the configurations according to FIGS. 3A to 3G are also possible. For example, part of the form body 6 is formed from the form body 15, a part is formed from the plates 14 and another part is formed from the rods 10. It is also possible that only the solid body 15, only the plates 14 or only the rods 10 are present and are connected, for example, to the heating plate 5 or the cooling plate 5. Bulges along only one of the longitudinal axis L and the transverse axis B or along both axes L, B are possible in the solid body 15, the plates 14 and the rods 10.

The degree of curvature is predetermined in particular by the different coefficients of thermal expansion of the PV laminate 1 with the glass pane 13 and the planar heat sink 13. The more different the coefficients of thermal expansion are, the more pronounced is the curvature of the top side 11. The curvature is configured to be as great as the curvatures that would occur due to the different coefficients of thermal expansion, but in the opposite direction along the upward direction Z. The degree of curvature of the top side 11 thus depends on the materials and/or alloys used of the layers of the layer stack 12, in particular of the material of the planar heat sink 3 and of the type of glass pane 13. In addition, the curvature of the top side 11 depends, for example, on the thickness of the layers of the layer stack 12. It is also possible that the curvature of the top side 11 depends on the type of planar heat sink 3, in particular on whether the planar heat sink 3 comprises two plates 3a, 3b (FIG. 4) or only a single plate 3b.

FIG. 4 shows an embodiment of the photovoltaic-thermal module 4.

The PVT module 4 according to FIG. 4 comprises the front glass 13. On a side opposite the front glass 13, there is a rear wall film 105. Several, for example crystalline, solar cells 102 are connected to one another via electrical cell connectors 103 and arranged between the front glass 13 and the rear wall film 105. The PVT module 4 is mechanically supported, for example, by a support frame 107 made of aluminum.

The PVT module 4 comprises the planar heat sink 3, in particular made of aluminum. Such planar heat sinks 3, also referred to as cooling plates, are used, for example, in automotive engineering. The planar heat sink 3 comprises, for example, two thin aluminum sheets 3a, 3b. In addition, a connector is provided for connecting the two sheets 3a, 3b. A channel structure having a plurality of cooling channels 3c is stamped into one of the two plates 3a, 3b, for example by a punching operation. This channel structure, for example, consists of many branches and is optimized to dissipate heat as efficiently as possible and to allow the lowest possible pressure losses.

The Al cooling plate 3 is, for example, glued or laminated to the rear wall film 105 by an adhesion layer 109.

The planar heat sink 3 according to FIG. 4 is based in particular on the aluminum plates 3a, 3b, which for example comprise a thickness of about 1 mm. An inner diameter of the cooling channels 3c is for example between 1 mm and 15 mm and can be different along the channels. It is also possible to form the planar heat sink 3 from glass plates. It is also possible to form the planar heat sink 3 only from a single plate 3b with the cooling channels 3c directly adjacent to the adhesion layer 109 or the rear wall film 105.

For example, the planar heat sink 3 comprises exactly one inlet and one outlet, which are not explicitly shown in FIG. 4. Based on the inlet and the outlet, the cooling channels 3c branch out so that the width of the cooling channels can decrease with increasing distance from the inlet and/or outlet. For example, the branches are bifurcations or trifurcations.

For example, the PVT module 4 is configured as described in patent application PCT/EP2022/072670. For example, the PVT module 4 is configured as described in patent application DE 10 2022 123 915.2. These references are incorporated herein by reference in their entirety.

Photovoltaic modules, or simply PV modules, are already a mainstay of today's energy supply and will become even more important in the future for a fossil-free and CO2-free energy supply. In the last 10 years, costs have fallen by about 90%, so that solar power is now the cheapest form of electricity generation worldwide. Nevertheless, a PV module today only converts about 20% of the solar energy it receives into electricity; the rest is lost as waste heat.

If this heat can be utilized, the overall efficiency of a PV module can be significantly increased. These modules are called photovoltaic-thermal modules or PVT modules for short. In addition to electrical energy, they also produce heat, usually in the form of hot water.

The PVT module 4 described here is based on the following considerations, among others: the materials used to manufacture the PVT modules 4 have different physical properties. The front cover of a solar module is usually made of glass, in particular glass pane 13. The cooling plate or heat exchanger plate, which can also be referred to as planar heat sink 3, is usually made of metal. Both materials have very different coefficients of thermal expansion. However, the two materials are preferably joined by a lamination process at high temperature. For example, by EVA foil, which can also be referred to as lamination film 3, at approx. 130 °C to 140 °C.

During the subsequent cooling process, the different coefficients of expansion can cause the layer stack 12 and/or the PVT module 4 to bend, since the aluminum contracts more than the glass. This results in mechanical stresses and can make it impossible to frame the module 4, i.e. to mount the support frame 107, for example. Furthermore, it can also affect long-term stability. In addition, the PVT module 4 not only bends when cooling down from the lamination temperature, but also during operation on the roof, where temperatures can also vary between −20°C/−40 °C and 80 °C.

The idea behind PVT Module 4, as described here, is to have the PVT module 4 as flat as possible at room temperature after lamination.

In one embodiment, after the lamination process, the module 4 is “overstretched” at high temperatures either in air or in a cooling press. That is, the mechanical lens 6, 7 is used, which can also be referred to as form body 6, 7, and on which the PVT module 4 is placed with the glass 13 facing downwards. For example, as a convex mold 6 on which the module 4 is placed. However, it can also be placed in the concave mold 7. This would have the added advantage that any protruding connectors, which can also be referred to as connectors 8, can be incorporated into the mold 7.

For example, the PVT module 4 cools in this form. The shape or bend exactly compensates for the deflection that would normally occur in the other direction of the PVT module 4, so that it is flat or almost flat at room temperature.

In a further embodiment, the PVT module 4 is already placed in the corresponding mold 6, 7 during the lamination process, so that the overstretching already takes place during the lamination at high temperatures, during which the materials actually connect with each other. This is even more effective.

Due to the lens shape of the mold 6, 7, this can also be referred to as a mechanical lens.

The mechanical lens 6, 7 can be made of metal or plastic, can be full-surface or only a skeleton structure (cost saving). It can also consist only of (metal) rods 10 of different heights or of metal plates 14 of different heights that are layered on top of each other. The structure can be milled from a solid piece or assembled in some other way.

It is also important to ensure that the temperature is transferred from the heating plate 5 to the structure 12 to be laminated and not to interrupt this transfer.

Furthermore, the structure can comprise a lens shape in a single direction L, B, but preferably in both directions L, B, so that the PVT module is flat in all directions at the end.

The PVT module 4 described here can be used in solar cells 102 of all types, for example crystalline or bifacial crystalline modules or thin-film modules. Furthermore, the following areas of application for the modules 4 are particularly considered: rooftop, industry, open space, low-temperature heating networks, floating systems (also known as floating PV), large open-space solar parks, especially in hot areas such as the USA, India, Spain, Arabia, Australia, Chile

The form bodies 6, 7 described here enable improved reliability and quality of the PVT modules by a double joint connection using adhesive bonding/lamination and clamping. A significant simplification in the production process is possible. Substantially less use of expensive materials, lower costs and higher economic efficiency can be realized.

The invention described herein is not limited by the description based on the embodiments. Rather, the invention comprises each new feature as well as each combination of features, which in particular includes each combination of features in the patent claims, even if this feature or combination is not explicitly stated in the patent claims or embodiments.

1-16. (canceled)

17. A form body configured for producing a photovoltaic module, the form body comprising:
a top side concavely or convexly curved in an upward direction configured for curving a layer stack of the photovoltaic module, the layer stack having at least two layers.

18. The form body according to claim 17, further comprising a plurality of flat extended plates stacked on top of each other along the upward direction, wherein the upward direction is aligned transverse to a flat extension.

19. The form body according to claim 18, further comprising a plurality of rods elongated along the upward direction, wherein the rods are arranged next to one another transversely to the upward direction.

20. The form body according to claim 17, wherein the form body is a solid body.

21. The form body according to claim 17, wherein the top side is configured as a full surface.

22. The form body according to claim 17, wherein the top side comprises a clearance.

23. The form body according to claim 17, wherein the top side is curved along only one longitudinal axis, and wherein the longitudinal axis extends transversely to the upward direction.

24. The form body according to claim 17, wherein the top side is curved along a longitudinal axis and along a transverse axis, and wherein each of the longitudinal axis and the transverse axis extends transversely to the upward direction.

25. The form body according to claim 17, wherein the form body comprises a heat conductivity of at least 30 W/(m·K).

26. The form body according to claim 17, wherein the form body comprises a plastic and/or a metal.

27. The form body according to claim 17, further comprising a recess for a connector of the photovoltaic module.

28. The form body according to claim 17, wherein the top side is curved depending on a coefficient of thermal expansion of at least two of the layers of the layer stack.

29. A method for processing a layer stack of a photovoltaic module, the method comprising:
stacking layers on a form body so that that the layer stack is provided and so that the layer stack rests against the form body thereby curving the layer stack using the form body; and
releasing the layer stack from the form body.

30. The method according to claim 29, further comprising heating the layer stack during a lamination of at least part of the layer stack while the layer stack is in contact with the form body.

31. The method according to claim 29, further comprising reducing a temperature of the layer stack while the layer stack is in contact with the form body.

32. The method according to claim 29, wherein providing the layer stack comprises providing the layer stack having at least one metallic planar heat sink and a glass pane.

33. The method according to claim 29, wherein the photovoltaic module is a photovoltaic-thermal module.
